(19) United States
(12) Patent Application Publication
(10) Pub. No.: US 2026/0120742 A1
(43) Pub. Date: Apr. 30, 2026

(54) DISTURBANCE-RESILIENT MEMORY ARCHITECTURE WITH INDEPENDENT PASS CONTROL FOR NON-VOLATILE TRANSISTOR ARRAYS

(71) Applicants: University of Notre Dame du Lac, South Bend, IN (US); The Penn State Research Foundation, University Park, NJ (US); Georgia Tech Research Corporation, Atlanta, GA (US)

(72) Inventors: Kai Ni, Notre Dame, IN (US); Vijaykrishnan Narayanan, State College, PA (US); Suman Datta, Atlanta, GA (US); Shimeng Yu, Atlanta, GA (US); Zijian Zhao, Mishawaka, IN (US)

(21) Appl. No.: 19/366,013

(22) Filed: Oct. 22, 2025

Related U.S. Application Data
(60) Provisional application No. 63/713,847, filed on Oct. 30, 2024.

(51) Int. Cl. G11C 11/22

(52) U.S. Cl. CPC G11C 11/2277; G11C 11/2259; G11C 11/2273; G11C 11/2275

(57) ABSTRACT

Non-volatile memory devices and methods are disclosed. A NAND memory string can include ferroelectric field-effect transistors each having a ferroelectric control gate and a separate non-ferroelectric pass gate. A program or read bias can be applied to the ferroelectric control gate of a selected transistor, while a pass bias is applied to the non-ferroelectric pass gate of at least one unselected transistor with its ferroelectric control gate held at a reference potential. This arrangement reduces depolarization field effects at high-threshold states and screens applied fields at low-threshold states, thereby maintaining stored polarization and reducing pass disturbance. The disclosed architecture can be incorporated into vertical FeFET NAND structures through a continuous or segmented conductive core or global bottom pass gate that is electrically coupled only to non-ferroelectric pass gates while ferroelectric control gates of unselected cells are held at a reference potential, to support three-dimensional integration.

### RELATED APPLICATIONS

This application claims the benefit of priority under 35 U.S.C. § 119(e) to U.S. Provisional Patent Application No. 63/713,847, filed Oct. 30, 2024, entitled “DUAL-PORT VERTICAL NAND STORAGE FOR PASS DISTURB-FREE OPERATION UTILIZING A STRING-COMPATIBLE PASS GATE”, which is incorporated herein by reference. Any and all applications for which a foreign or domestic priority claim is identified in the Application Data Sheet as filed with the present application are incorporated by reference under 37 CFR 1.57 and made a part of this specification.

### STATEMENT OF GOVERNMENT SUPPORT

This invention was made with government support under Award No. HR0011-23-3-0002, awarded by the Defense Advanced Research Projects Agency (DARPA), and Award No. FA8702-15-D-0001, awarded by the United States Air Force. The government has certain rights in the invention.

### FIELD

The present disclosure generally relates to non-volatile semiconductor memory devices and, more particularly, to array architectures and device structures for enhancing reliability in high-density memory systems.

### BACKGROUND

Non-volatile memory technologies are widely deployed in modern computing systems to provide persistent storage with high density and low power consumption. As demand continues to grow for faster, more reliable, and more scalable storage, memory designers have explored three-dimensional (3D) integration approaches to overcome the limitations of traditional planar scaling.

Vertical NAND flash memory has become a prominent candidate for achieving high-density integration, as stacking multiple memory layers in the vertical direction allows for significant improvements in storage capacity. In such array structures, memory cells are typically accessed through pass transistors that enable selective read and program operations along memory strings.

However, in densely stacked memory arrays, operational disturbances can arise when voltages applied to access or pass transistors inadvertently affect the stored states of non-targeted memory cells. Such disturbances can impact data retention, endurance, and the scalability of advanced memory technologies.

### SUMMARY

Non-volatile memory devices and methods are disclosed. A NAND memory string can include ferroelectric field-effect transistors each having a ferroelectric control gate and a separate non-ferroelectric pass gate. A program or read bias can be applied to the ferroelectric control gate of a selected transistor, while a pass bias is applied to the non-ferroelectric pass gate of at least one unselected transistor with its ferroelectric control gate held at a reference potential. This arrangement reduces depolarization field effects at high-threshold states and screens applied fields at low-threshold states, thereby maintaining stored polarization and reducing pass disturbance. The disclosed architecture can be incorporated into vertical FeFET NAND structures through a continuous or segmented conductive core or global bottom pass gate that is electrically coupled only to non-ferroelectric pass gates while ferroelectric control gates of unselected cells are held at a reference potential, to support three-dimensional integration.

### BRIEF DESCRIPTION OF THE DRAWINGS

Throughout the drawings, reference numbers can be re-used to indicate correspondence between referenced elements. The drawings are provided to illustrate embodiments of the present disclosure and do not to limit the scope thereof.

FIG. 1A illustrates an example of a vertical NAND storage structure, which may be implemented using flash transistors or ferroelectric field-effect transistors (FeFETs).

FIG. 1B illustrates an example of a single-port three-dimensional (3D) NAND configuration.

FIG. 1C illustrates an example of a dual-port three-dimensional (3D) NAND configuration.

FIG. 1D illustrates an example of a global self-boosting program inhibition scheme used in single-port vertical NAND.

FIG. 1E illustrates an equivalent circuit representation of a selected NAND string during program and inhibit operations.

FIG. 1F illustrates the relationship between the applied pass voltage (VPASS) and disturbance effects in a vertical NAND string.

FIG. 1G illustrates an example programming bias scheme for a dual-port vertical NAND array.

FIG. 1H illustrates an equivalent circuit model for a dual-port vertical NAND string.

FIG. 1I illustrates the disturbance characteristics for example dual-port vertical NAND configurations.

FIGS. 2A and 2B illustrate examples of single-port FeFETs that can be subject to pass disturbance.

FIGS. 2C and 2D illustrate examples of dual-port FeFETs in which the write gate (WG) includes the ferroelectric dielectric, while a separate nonferroelectric pass gate (PG) can be used to provide pass functionality.

FIG. 2C illustrates a dual-port FeFET in a low-threshold-voltage (LVT) state.

FIG. 2D illustrates a dual-port FeFET in a high-threshold-voltage (HVT) state.

FIG. 2E illustrates an example FEOL device, implemented as a fully depleted silicon-on-insulator (FDSOI) FeFET.

FIG. 2F illustrates a transmission electron microscopy (TEM) image of the device of FIG. 2E integrated on a 22 nm FDSOI platform.

FIGS. 2G and 2H illustrate simulated results obtained from technology computer-aided design (TCAD) models of the FDSOI transistor.

FIGS. 2I and 2J illustrate electrical characteristics obtained from FDSOI FeFETs.

FIG. 2K illustrates an example effect of applying a pass bias (VPASS) to the write gate in a single-port FeFET.

FIG. 2L illustrates the effect of applying a pass bias to the pass gate in a dual-port FeFET.

FIG. 3A illustrates an example setup and applied waveforms for a single-port FeFET-based NAND string composed of three transistors (T1, T2, T3).

FIG. 3B illustrates the measured ID-VG characteristics of transistors T1 and T3 in the single-port NAND string when T2 is biased at VPASS=2 V.

FIG. 3C illustrates the ID-VG characteristics of transistor T2 when designated as the selected cell, with VPASS applied to T1 and T3.

FIG. 3D illustrates characterization of pass disturb in the single-port NAND string.

FIG. 3E illustrates read disturb characterization of T1 and T3 in the single-port string.

FIG. 3F illustrates the configuration and applied waveforms for a dual-port FeFET NAND string including transistors T1, T2, and T3.

FIG. 3G illustrates the ID-VG characteristics of T1 and T3 in the dual-port string when the unselected transistor T2 is in the LVT state.

FIG. 3H illustrates the ID-VG characteristics of T1 and T3 when the unselected transistor T2 is in the HVT state.

FIG. 3I illustrates pass disturb characterization of the dual-port NAND string by measuring the VTH of T2 after application of pass bias to the pass gate, with the write gate of T2 grounded.

FIG. 3J illustrates further disturb characterization of transistor T2 in the dual-port NAND string under VPASS values ranging from 9 V to 15 V.

FIG. 4A illustrates a cross-section of a simulated dual-port memory cell including a ferroelectric layer (FE), a channel region, a central conductive pass-gate core electrically coupled to a non-ferroelectric pass gate, and a surrounding non-ferroelectric dielectric.

FIG. 4B illustrates a three-dimensional model of an eight-word-line (8-WL) dual-port vertical NAND string.

FIG. 4C illustrates erase, write, and read waveforms used in simulation with WL₃ as the selected cell.

FIG. 4D illustrates a simulated electric-field distribution in a single-port string.

FIG. 4E illustrates a corresponding distribution for a dual-port string in which VPASS is applied to the central pass gate.

FIG. 4F illustrates a vertical NAND-compatible 3D structure that incorporates a conductive pass-gate core within each memory hole and a pass-gate contact formed in the substrate region.

FIG. 4G illustrates a top view showing multiple memory holes with centrally located pass-gate cores, demonstrating array-level placement without alteration of cell pitch.

FIG. 4H illustrates a cross-section along cutline B-B′ showing word lines (WL), select lines, and the central pass gate integrated within the vertical channel.

FIG. 4I illustrates a cross-section along cutline A-A′ further detailing the stacked word-line arrangement and the central pass-gate geometry within the memory holes.

FIG. 5A illustrates a schematic view of a dual-port BEOL indium-tungsten-oxide (IWO) FeFET.

FIG. 5B illustrates drain current (ID) versus back-gate voltage (VBG) characteristics of a single-port IWO FeFET.

FIG. 5C illustrates the threshold voltage (VTH) shift of a single-port IWO FeFET measured under varying read times and different pass voltages.

FIG. 5D illustrates a cumulative probability distribution of the cycle-to-cycle drain-source conductance (GDS) shift for the single-port IWO FeFET.

FIG. 5E illustrates drain current (ID) versus back-gate voltage (VBG) characteristics of a dual-port IWO FeFET.

FIG. 5F illustrates the threshold voltage (VTH) behavior of the dual-port IWO FeFET measured under varying read times and pass voltages.

FIG. 5G illustrates the cumulative probability distribution of cycle-to-cycle drain-source conductance (GDS) shifts for the dual-port IWO FeFET.

FIG. 6A illustrates the electric field distribution when a pass voltage (VPASS) of 1 V is applied.

FIG. 6B illustrates the electric field distribution when a pass voltage (VPASS) of 2 V is applied.

FIG. 7 illustrates an example process integration flow for forming a dual-port vertical FeFET-based NAND string in which a dedicated pass gate is incorporated into the central core region of the array.

### DETAILED DESCRIPTION

### Introduction

As three-dimensional (3D) NAND architectures continue to scale to hundreds and even thousands of stacked layers, conventional single-port access schemes face growing reliability and margin challenges. In particular, the use of a high pass voltage (V_{PASS}) on unselected word lines to convey channel potentials during read and program operations can couple electric fields into ferroelectric or charge-storage stacks, shifting threshold-voltage (V_{TH}) distributions and narrowing state separations. These pass-disturb mechanisms degrade retention and endurance, complicate program-inhibit biasing, and constrain array scalability and operating windows. There is therefore a need for memory string architectures and biasing methods that maintain sufficient channel conduction for sensing and program-inhibit while isolating the storage element from pass-related electric fields, thereby preserving stored polarization states and improving array robustness. Unlike split-gate flash or dummy-gate pass schemes, some architectures disclosed herein explicitly separate a ferroelectric control gate from a dedicated non-ferroelectric pass gate and route VPASS exclusively to the non-ferroelectric structure, limiting or preventing application of VPASS to ferroelectric gates of unselected cells.

Some inventive concepts described herein relate to non-volatile NAND strings that separate the function of data storage from the function of pass conduction. In some cases, each FeFET memory cell is formed with both a ferroelectric control gate for storing information and a distinct non-ferroelectric pass gate for establishing channel conduction. During read or program operations, a bias may be applied to the ferroelectric control gate of a selected cell, while a pass bias is applied only to the non-ferroelectric pass gates of unselected cells. In some cases, the pass bias is applied exclusively to the non-ferroelectric pass gates and is not applied to any ferroelectric control gate of unselected cells, and the ferroelectric gates of unselected cells are kept at a reference potential (e.g., 0 V or a negative clamp. As used herein, the reference potential can include, but is not limited to, ground (0 V), a negative clamp between −0.3 V and −1.5 V, or a mid-rail level between 0.2 VDD and 0.6 VDD, selected to suppress unintended ferroelectric switching. By keeping the ferroelectric gates of unselected cells at a reference potential, the architecture enables current flow along the string without exposing stored ferroelectric states to disruptive pass voltages. This configuration reduces pass-disturb effects and improves data retention, even under repeated cycling and extended operation.

Some inventive concepts described herein relate to vertical NAND arrangements in which the non-ferroelectric pass gates are coupled to a conductive structure (e.g., a metallic) core running through each memory pillar. The conductive structure/core can serve as a global or segmented pass-gate line, accessible through a single contact, thereby simplifying array wiring while preserving the independence of the ferroelectric storage gates. In some implementations, the alternating stack of ferroelectric control gates and non-ferroelectric pass gates forms a three-dimensional memory array in which each type of gate can be driven separately. This structural separation allows for robust inhibit schemes, reliable sensing, and improved scalability of ferroelectric NAND technology to higher layer counts. In some segmented embodiments, independently biasable sections of the conductive core limit IR drop and RC loading while maintaining isolation of ferroelectric gates at the reference potential during pass operations.

By routing pass conduction through a dedicated, non-ferroelectric gate shared along the string, some embodiments of the disclosed architectures maintain stable operation under extended pass-bias conditions and reduce sensitivity to the highest threshold-voltage states. VPASS may be selected according to channel conduction requirements rather than constrained by disturb thresholds of ferroelectric stacks, which broadens the operating margins for read, program, and inhibit. Vertical pillar implementations with metallic cores or segmented conductors serving the pass gates preserve conventional 3D NAND geometries and word-line pitch, supporting high-layer-count integration with minimal interconnect overhead. Collectively, these methods and structures improve data integrity, enhance sensing reliability, and provide scalability for FeFET-based and related vertical NAND technologies. For example, Because V_{PASS} is not applied to ferroelectric control gates of unselected cells, polarization states remain substantially undisturbed across extended pass stress.

Some presently disclosed embodiments improve the reliability and scalability of ferroelectric NAND arrays by decoupling the pass-gating function from the ferroelectric storage element. These improvements address technical challenges observed in conventional single-port FeFET NAND strings, including pass-disturb induced threshold drift, state degradation under repeated VPASS biasing, and reduced endurance in high-layer stacks. The disclosed systems provide technical solutions through dual-gate memory cells, including a ferroelectric control gate for storage and a distinct non-ferroelectric pass gate for conduction, together with array-level architectures that allow independent biasing of the respective gate types. A shared or segmented conductive core may supply V_{PASS} exclusively to the non-ferroelectric pass gates while the ferroelectric control gates of unselected cells are maintained at the reference potential, thereby avoiding exposure of the ferroelectric stack to pass bias. By separating these functions, the architectures sustain stable operation under extended pass-bias conditions, maintain robust data retention, and support consistent multi-level cell distributions. Collectively, these attributes deliver improved disturb immunity and stronger scalability, marking a substantial advancement over conventional FeFET NAND implementations for high-density three-dimensional non-volatile memory.

### Example Single-Port and Dual-Port Vertical NAND Architectures

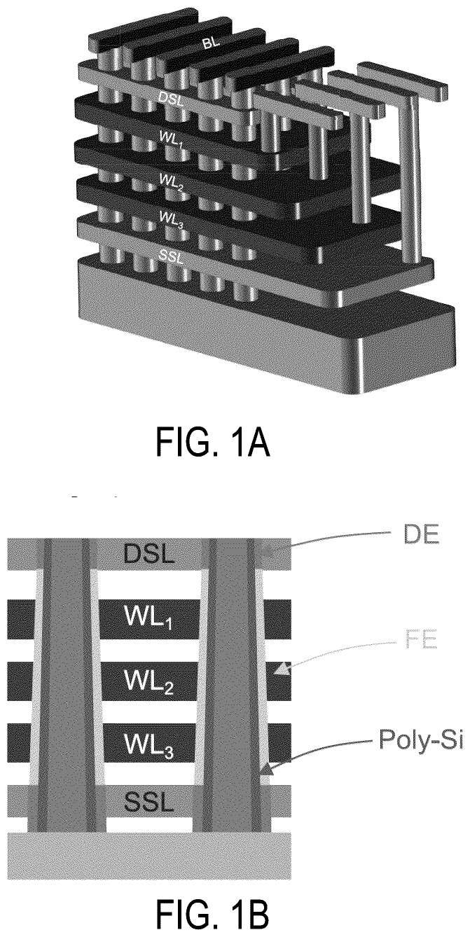

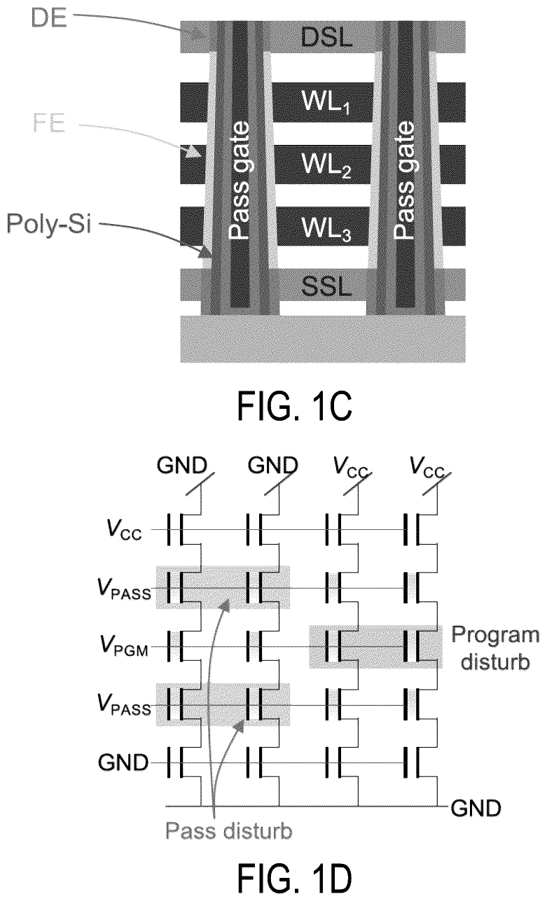

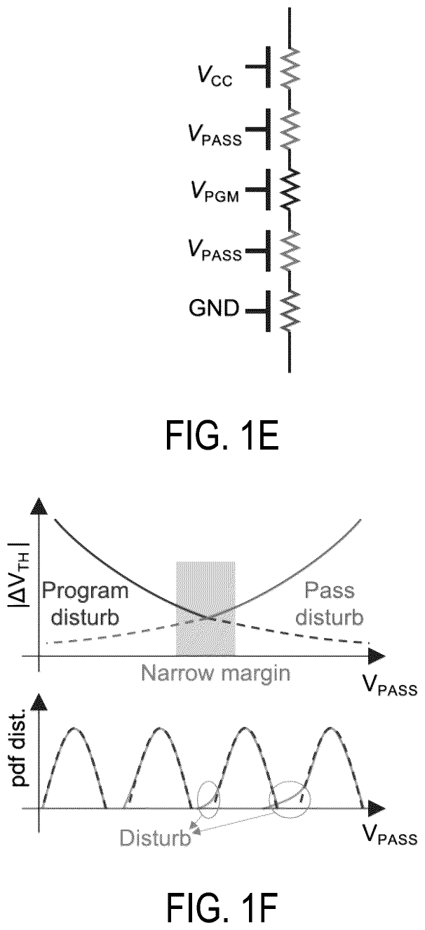

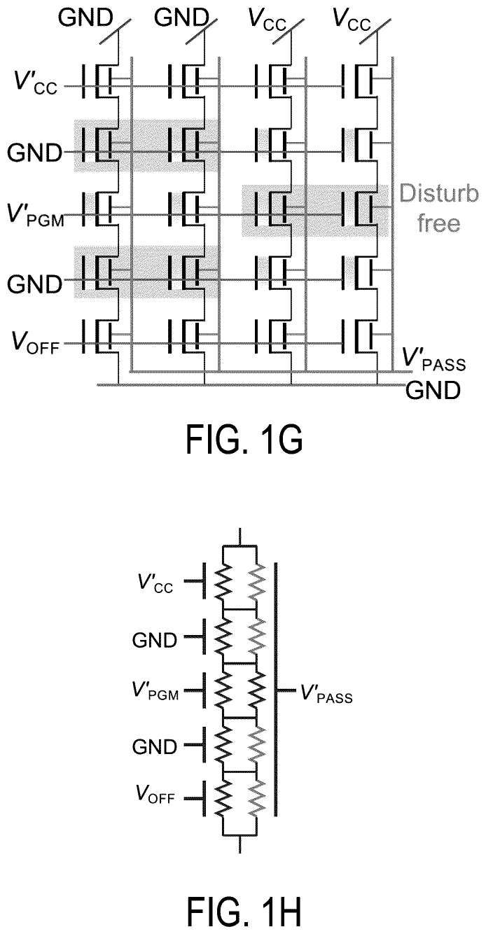

Vertical NAND flash storage has been widely adopted in digital storage systems due to its high density and low cost. FIG. 1A illustrates an example of a vertical NAND storage structure, which may be implemented using flash transistors or ferroelectric field-effect transistors (FeFETs). The structure includes multiple vertically stacked word lines (WL₁, WL₂, WL₃), a bit line (BL), a source line (SSL), and a drain select line (DSL). The stacking arrangement can be used to achieve high memory density through the integration of multiple layers of memory cells in a three-dimensional configuration.

Modern vertical NAND designs can attain high density by stacking memory layers in a cross-sectional arrangement, with state-of-the-art devices already exceeding 200-300 layers and advancing toward more than 1000 layers. In addition to conventional flash transistors, other memory device types have been investigated to reduce operating voltage and improve switching speed. For example, ferroelectric field-effect transistors (FeFETs) have been studied following the observation of ferroelectricity in thin doped hafnium oxide (HfO₂) films. Sharing a similar transistor architecture, vertical FeFET structures have been reported to provide multibit storage capability through partial polarization switching, along with efficient switching behavior suited for high-density storage.

Some aspects of the inventive concepts relate to vertical NAND arrays configured a single-port arrangement. For example, FIG. 1B illustrates an example of a single-port three-dimensional (3D) NAND configuration. The structure includes vertically stacked word lines (WL₁, WL₂, WL₃), a source line (SSL), and a drain select line (DSL). A dielectric (DE), ferroelectric material (FE), and polysilicon (Poly-Si) region are also shown as representative elements within the device stack.

Some aspects of the inventive concepts relate to vertical NAND arrays configured in dual-port arrangements. For example, FIG. 1C illustrates an example of a dual-port three-dimensional (3D) NAND configuration. The structure includes vertically stacked word lines (WL₁, WL₂, WL₃), a source line (SSL), and a drain select line (DSL). In this arrangement, independent pass gate regions can be used in conjunction with the stacked word lines to provide an alternative access configuration. In some embodiments, the independent pass functionality is provided by a conductive core that is continuous or segmented into independently biasable sections; segments may span 8-64 word lines and be formed by dielectric breaks or air-gap interruptions with optional via straps, meeting pass-network design targets of V_{PASS} IR drop<100 mV at Iₚₐₛₛ, line resistance<5 mΩ/μm, and effective pass-line capacitance<30 fF/WL.

Due to its serial structure, a vertical NAND array can be more susceptible to disturbance effects during read and write operations compared to other types of memory arrays. To read a target cell in a conventional single-port vertical NAND string, both program and pass biases are applied on the same gate (i.e., word line). In this configuration, unselected cells in the string receive a relatively large pass voltage (V_{PASS}) in order to transfer voltages from the string ends to the target cell. The applied V_{PASS} is typically set higher than the highest threshold voltage (VTH) so that unselected cells turn ON regardless of their stored state. However, the use of a high V_{PASS} can also disturb memory states. The choice of V_{PASS} may become especially relevant during programming operations, where it should be adjusted to balance the risks of pass disturb and program disturb.

FIG. 1D illustrates an example of a global self-boosting program inhibition scheme used in single-port vertical NAND. After a block erase, the target cells on the selected page are programmed while the other cells on the same page are inhibited. This is achieved by applying ground and V_{CC} to selected and unselected cells, respectively. In this way, the selected cells receive sufficient voltage to be programmed, while the unselected strings are floating and their channel potential is raised by the applied voltages to inhibit programming.

FIG. 1E illustrates an equivalent circuit representation of a selected NAND string during program and inhibit operations. In this model, the conduction state of cells that are turned ON by an applied pass voltage (V_{PASS}) is represented by resistors. The circuit includes a supply voltage (V_{CC}) applied at one end of the string, ground (GND) applied at the opposite end, and intermediate nodes subject to V_{PASS} and the program voltage (V_{PGM}). The resistive elements model the effective channel conduction of ON cells, allowing the circuit to capture how voltages are transferred along the string. This representation can be used to analyze the impact of different biasing conditions on voltage distribution and disturbance effects within the array.

FIG. 1F illustrates the relationship between the applied pass voltage (V_{PASS}) and disturbance effects in a vertical NAND string. The upper graph shows the change in threshold voltage (|ΔV_{TH}|) as a function of V_{PASS}. To ensure that unselected cells are turned ON regardless of their threshold voltage (V_{TH}), V_{PASS} is applied at a level greater than the highest V_{TH} in the string. At higher V_{PASS}, charge coupling through the gate stack can give rise to pass disturb in unselected cells. At lower V_{PASS}, channel boosting may be insufficient, which can allow unintended programming, referred to as program disturb. The interplay of these two tendencies results in a relatively narrow operating window for V_{PASS}, within which both types of disturbance are present but may be moderated.

The lower graph of FIG. 1F depicts the statistical distribution of threshold voltages across multiple memory states. Probability density functions (pdf) of the programmed states can shift or broaden under disturbance conditions, which reduces the separation between adjacent distributions. This illustrates the difficulty in selecting a V_{PASS} condition that balances the competing disturbance effects while maintaining adequate distinction among stored states. As used herein, a disturb threshold may refer to a stress condition under which an unselected ferroelectric device exhibits |ΔVTH|≤50 mV after 1 ms at 25° C. under application of V_{PASS} (and <100 mV after 1 ms at 85° C.), absent program-verify.

Some inventive concepts described herein can address these or other issues by employing a dual-port vertical NAND configuration, such as shown in FIG. 1C. The configuration of FIG. 1C includes an independent pass gate (PG) located in the core of the NAND string, implemented with a nonferroelectric gate dielectric. The pass gate can be used to turn ON the string channel during passing operations. In this way, the dual-port arrangement can be incorporated into a vertical NAND array without introducing significant overhead from the additional gate. In some cases, during such pass operations, V_{PASS} is delivered through the core to the non-ferroelectric pass gates while ferroelectric control gates of unselected cells remain clamped at a reference potential. As used herein, reference potential can include, but is not limited to, ground (0 V), a negative clamp between −0.3 V and −1.5 V, or a mid-rail level between 0.2·VDD and 0.6·VDD, selected to suppress unintended ferroelectric switching.

FIG. 1G illustrates an example programming bias scheme for a dual-port vertical NAND array. In this arrangement, the pass operation is carried out by a dedicated pass gate rather than by the ferroelectric gates of the memory cells. The illustrated scheme applies supply and ground voltages across different nodes of the string, while program and inhibit conditions are established through the dedicated pass gate. Because the pass function is isolated in this way, unselected cells in the same string no longer receive a high V_{PASS} on their ferroelectric gates. This may prevent or limit the charge-coupling effects that lead to pass disturb in single-port arrays. Representative bias windows can include V_{READ}≈0.5-2 V applied to the selected ferroelectric control gate, V_{PGM}≈3-8 V for planar FEOL embodiments and ≈6-15 V for vertical embodiments, and V_{PASS}≈4-15 V applied only to the conductive core/pass network; pulse widths may range from 50 ns to 10 ms with duty cycles of 5-20% depending on array geometry.

The diagram further shows that the dedicated pass gate provides a controlled conduction path through the channel, while unselected cells remain biased at levels that avoid unintentional programming. In this manner, disturb-free operation can be achieved during programming, with the voltage distribution across the string maintained without applying V_{PASS} to any ferroelectric control gate of unselected cells and/or while those ferroelectric gates are held at the reference potential defined herein.

FIG. 1H illustrates an equivalent circuit model for a dual-port vertical NAND string. Here, the dedicated pass gate can be used to provide a conduction path that is activated independently of the ferroelectric memory gates. When the pass gate is turned ON, the channel can become conductive from the back of the string, allowing voltages applied at the source and drain ends to be conveyed to selected cells.

The resistive elements in the circuit model can represent memory cells that are in an ON state, while other nodes can be biased at levels corresponding to program, pass, or inhibit conditions. By routing the pass function through the dedicated gate, the circuit shows how channel conduction can be established without applying elevated V_{PASS} to unselected ferroelectric devices. This arrangement can support biasing conditions that preserve cell integrity and reduce susceptibility to disturbance during array operation. In some cases, the circuit representation demonstrates how conduction can be established through the channel without the need for elevated V_{PASS} on the ferroelectric gates of unselected cells. In some reads, the source select line (SSL) and drain select line (DSL) are biased ON to couple the source line (e.g., 0 V) and bit line (at a small read bias) to the string; string current flows because V_{PASS} is supplied via the conductive core to the non-ferroelectric pass gates, while the ferroelectric control gates of all unselected cells are maintained at the reference potential.

FIG. 1I illustrates the disturbance characteristics for example dual-port vertical NAND configurations. Because conduction can be provided by the pass gate, V_{PASS} is not applied to the ferroelectric gates, and disturbance mechanisms associated with pass biasing can be absent.

The upper graph shows that threshold voltage shifts (|ΔV_{TH}|) related to pass disturb can be reduced or eliminated across the range of V_{PASS}. The lower graph depicts probability density functions (pdf) of programmed states that can retain separation without additional broadening. These characteristics indicate that memory state distributions can be preserved with reduced susceptibility to pass-related disturbance.

As described herein, operation that substantially avoids pass disturbance can be achieved in a dual-port ferroelectric field-effect transistor (FeFET) configuration. Such operation can be realized in front-end-of-line (FEOL) and/or back-end-of-line (BEOL) HfO₂-based FeFET devices, including NAND FeFET strings. In addition, technology computer-aided design (TCAD) studies can be used to examine the behavior of scaled vertical FeFET structures.

### Dual-Port FeFET Enabling Disturb-Free Operation

Pass disturbance can occur in single-port ferroelectric field-effect transistors (FeFETs) because the same ferroelectric gate is used for write, read, and pass operations. When a pass voltage is applied in this configuration, the resulting electric field can interact with the polarization in ways that either support or degrade the stored state depending on the programmed threshold voltage. By contrast, a dual-port FeFET structure, as described herein, can separate the programming and pass functions, where the ferroelectric gate can establish the channel polarization and a nonferroelectric pass gate can provide conduction for read and pass operations. This separation can influence how applied biases interact with the ferroelectric polarization and may reduce susceptibility to disturbance.

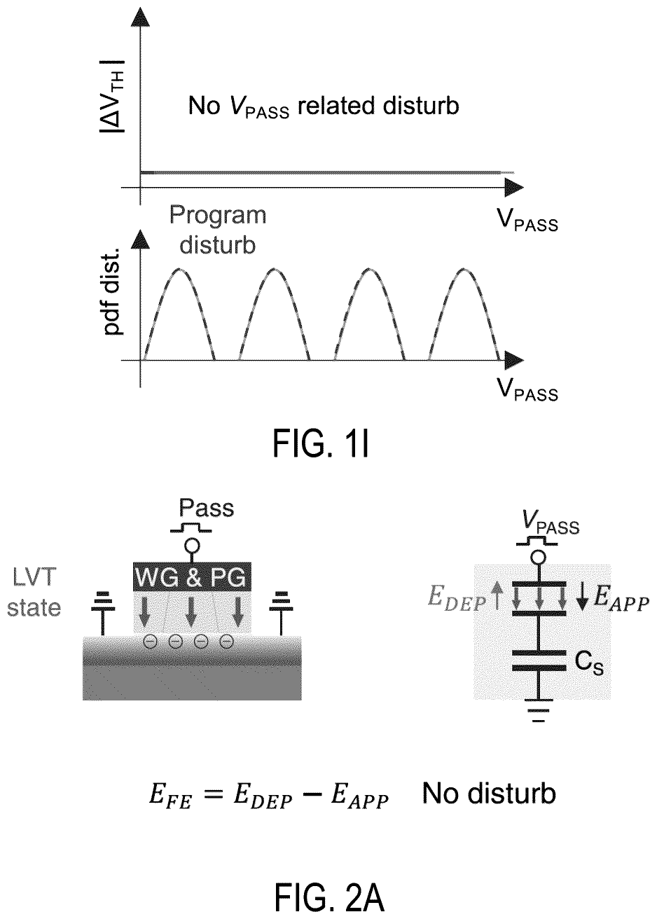

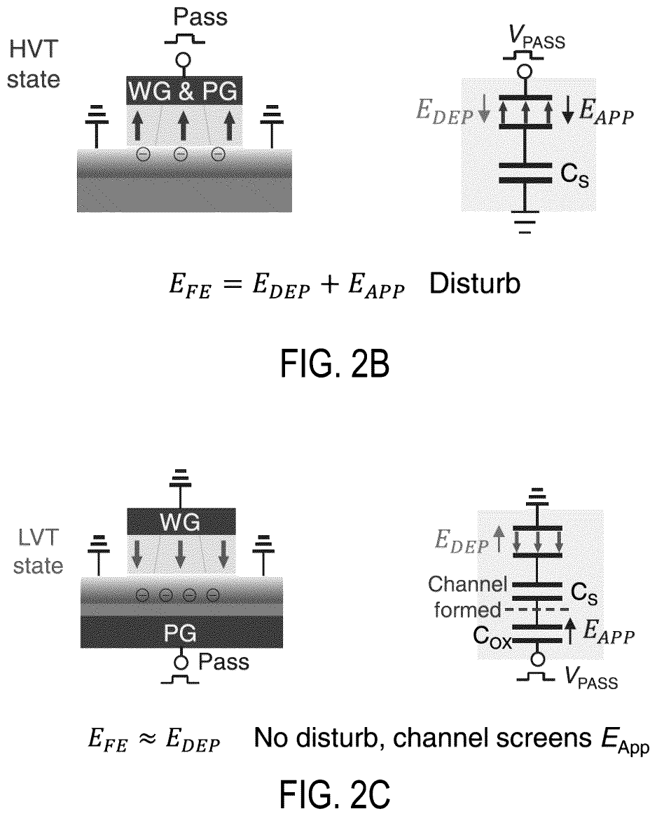

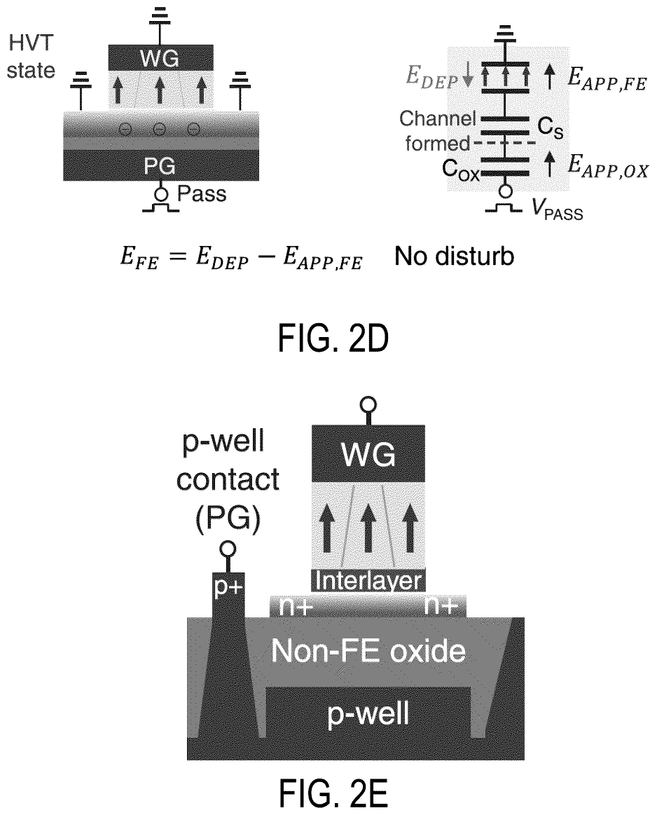

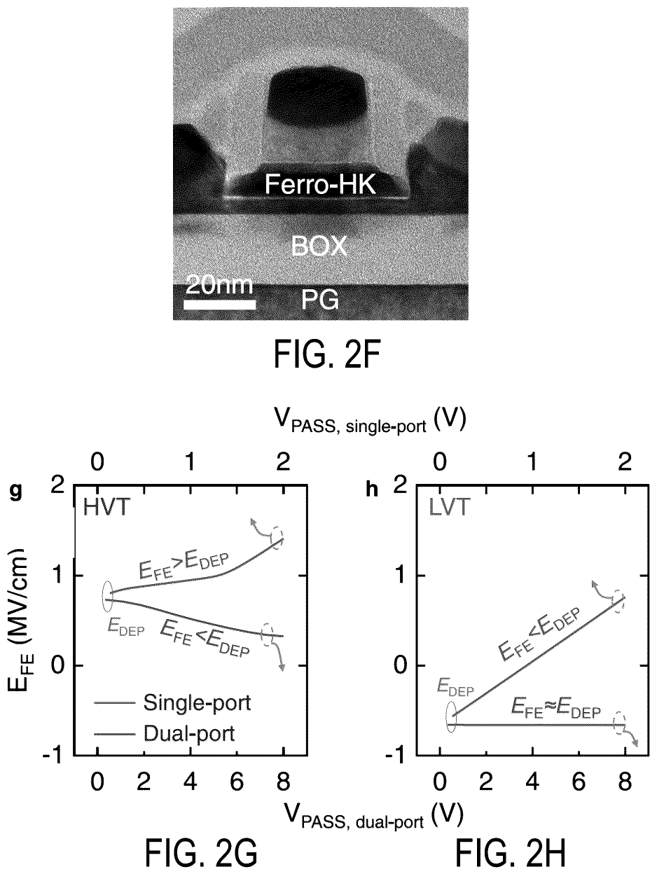

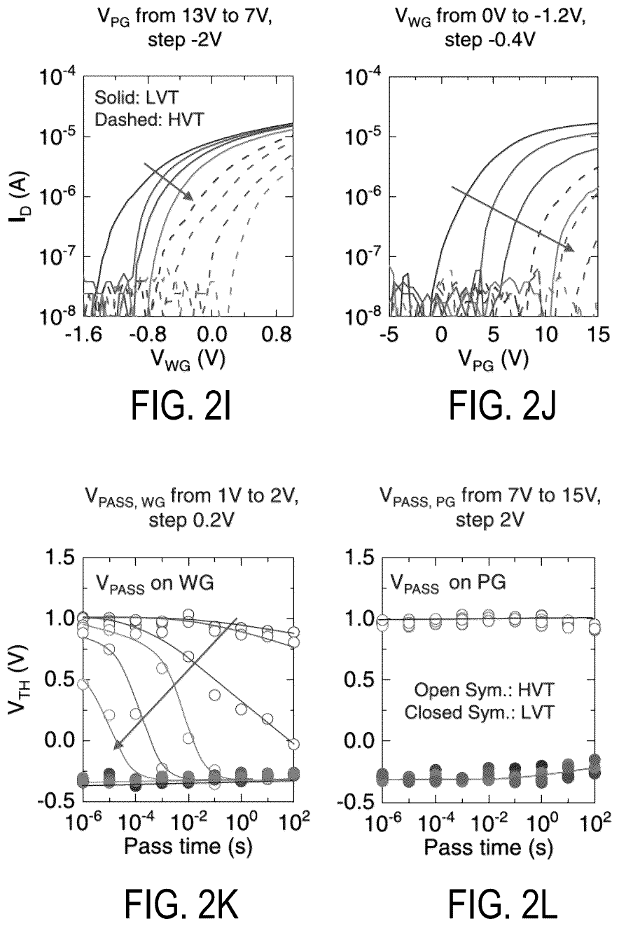

FIGS. 2A and 2B illustrate examples of single-port FeFETs that can be subject to pass disturbance. In this configuration, write, read, and pass operations are all carried out through the same gate that includes the ferroelectric film. In the low-threshold-voltage (LVT) state shown in FIG. 2A, application of a pass voltage (V_{PASS}) can generate an applied electric field (E_{APP}) aligned with the polarization. In this condition, the depolarization field (E_{DEP}) can be reduced, and the polarization state can be maintained with relative stability. In the high-threshold-voltage (HVT) state shown in FIG. 2B, the applied E_{APP} can oppose the polarization, which can enhance the depolarization field and lead to degradation of the stored state. For example, when a pass voltage is applied, the applied field (E_{APP}) is oriented against the polarization, which can reinforce the depolarization field (E_{DEP}). Under such conditions, the polarization state can become less stable, leading to susceptibility to retention loss. For other intermediate states, the degree of disturbance can fall between the behaviors observed in the LVT and HVT states.

FIGS. 2C and 2D illustrate examples of dual-port FeFETs in which the write gate (WG) includes the ferroelectric dielectric, while a separate nonferroelectric pass gate (PG) can be used to provide pass functionality. In this configuration, programming and passing functions are separated. Because the polarization set through the ferroelectric gate can influence the channel carrier concentration, this channel condition can also be sensed through the nonferroelectric gate. This structural property can support operation that is less susceptible to pass-related disturbance.

FIG. 2C illustrates a dual-port FeFET in a low-threshold-voltage (LVT) state. The structure includes a write gate (WG) overlying a ferroelectric dielectric layer, a pass gate (PG) overlying a nonferroelectric dielectric layer, a semiconductor channel region, and an underlying substrate. When a pass bias (V_{PASS}) is applied to the pass gate, an applied electric field (E_{APP}) can be directed against the ferroelectric polarization. In this state, the channel can become conductive, and the applied bias can be screened by carriers present in the channel. As a result, little or no field reaches the ferroelectric layer. The effective field across the ferroelectric (E_{FE}) can therefore approximate the depolarization field (E_{DEP}), and the polarization state can be retained without exhibiting pass disturbance.

FIG. 2D illustrates a dual-port FeFET in a high-threshold-voltage (HVT) state. As in FIG. 2C, the device includes the write gate, pass gate, ferroelectric dielectric layer, nonferroelectric dielectric layer, channel region, and substrate. When a pass bias (V_{PASS}) is applied, the resulting applied field (E_{APP,FE}) can align with the polarization in the ferroelectric layer. This alignment can support retention of the stored state, such that the effective field across the ferroelectric (E_{FE}) can be expressed as the depolarization field reduced by the applied field component (E_{DEP}−E_{APP,FE}). Under these conditions, the dual-port configuration can operate without, or with little, pass disturbance.

### Representative Device Structures and Characteristics

Various implementations can be used to illustrate the operation of dual-port ferroelectric field-effect transistors (FeFETs) and their ability to maintain memory states under pass bias. Representative structures, simulations, and electrical measurements are provided to demonstrate how such devices can be realized in both FEOL and BEOL configurations. These examples show physical device layouts, modeled depolarization field behaviors, transfer characteristics, and biasing effects on programmed states. Dual-port FeFETs can be implemented in both FEOL and BEOL configurations.

FIG. 2E illustrates an example FEOL device, implemented as a fully depleted silicon-on-insulator (FDSOI) FeFET. In this structure, the ferroelectric layer overlies the silicon channel, the buried oxide (BOX) serves as the nonferroelectric dielectric, and a p-well contact can provide pass-gate functionality.

FIG. 2F illustrates a transmission electron microscopy (TEM) image of the device of FIG. 2E integrated on a 22 nm FDSOI platform.

FIGS. 2G and 2H illustrate simulated results obtained from technology computer-aided design (TCAD) models of the FDSOI transistor. For the high-threshold-voltage (HVT) state, shown in FIG. 2G, the depolarization field can be enhanced in a single-port device, whereas it can be reduced in a dual-port device. For the low-threshold-voltage (LVT) state, shown in FIG. 2H, the depolarization field can be reduced in the single-port device, while in the dual-port device the field can remain substantially constant due to channel screening.

FIGS. 2I and 2J illustrate electrical characteristics obtained from FDSOI FeFETs. FIG. 2I shows I_{D}-V_{G} curves measured by sweeping the ferroelectric write gate (WG), while FIG. 2J shows I_{D}-V_{G} curves measured by sweeping the nonferroelectric pass gate (PG). In each case, the threshold voltage (V_{TH}) can be tuned linearly with the bias applied to the other gate. A comparatively larger memory window can be observed for the pass-gate sweep, which can result from the larger equivalent oxide thickness (EOT) associated with the nonferroelectric layer.

FIG. 2K illustrates an example effect of applying a pass bias (V_{PASS}) to the write gate in a single-port FeFET. Under these conditions, the HVT state can be disturbed, while the LVT state can remain stable.

FIG. 2L illustrates the effect of applying a pass bias to the pass gate in a dual-port FeFET. In this configuration, both the HVT and LVT states can remain stable under the pass bias.

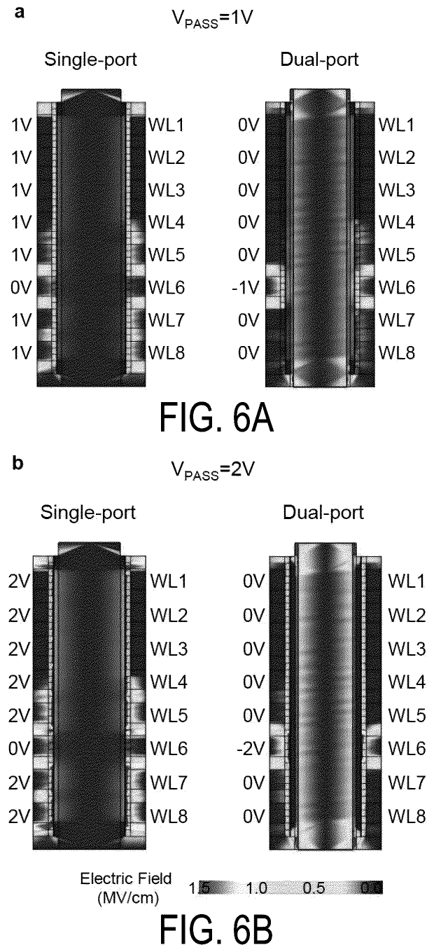

A further example of a dual-port FeFET can be implemented in a BEOL configuration, in which the ferroelectric layer is positioned beneath an amorphous metal-oxide thin-film channel, such as tungsten-doped indium oxide (IWO), with a nonferroelectric layer disposed above the channel, as shown in FIGS. 6A and 6B.

### Pass Disturb-Free Operation in Nand FeFET String

Pass disturb-free operation in a NAND FeFET string can be demonstrated using representative three-transistor strings that capture features of a NAND array. Both single-port and dual-port configurations can be characterized to evaluate the susceptibility of memory states to pass bias stress. The results confirm that, while single-port strings exhibit severe pass disturb at elevated VPASS values, in some cases, the dual-port architecture eliminates such disturb and thereby enables reliable disturb-free NAND operation.

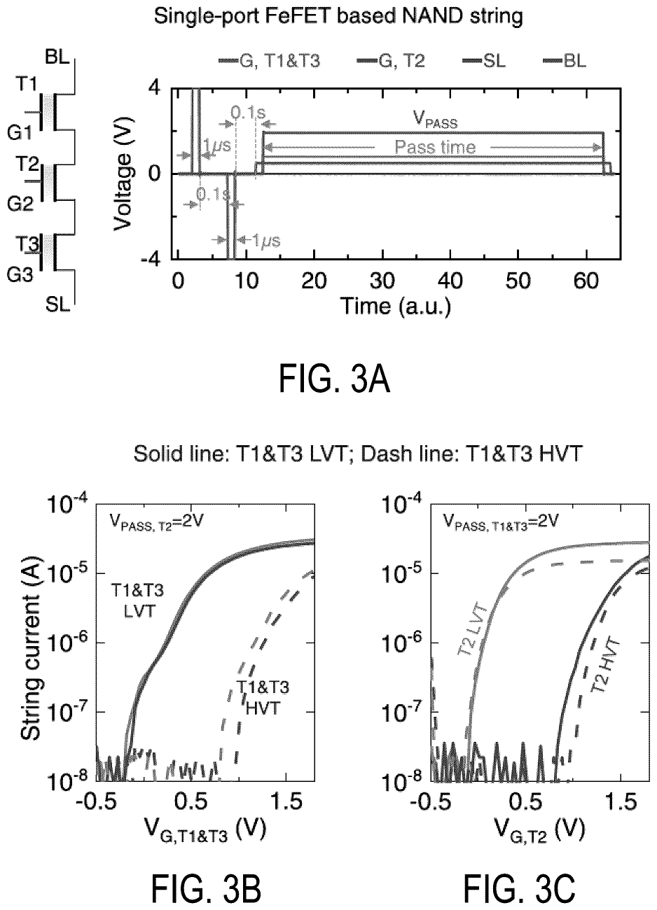

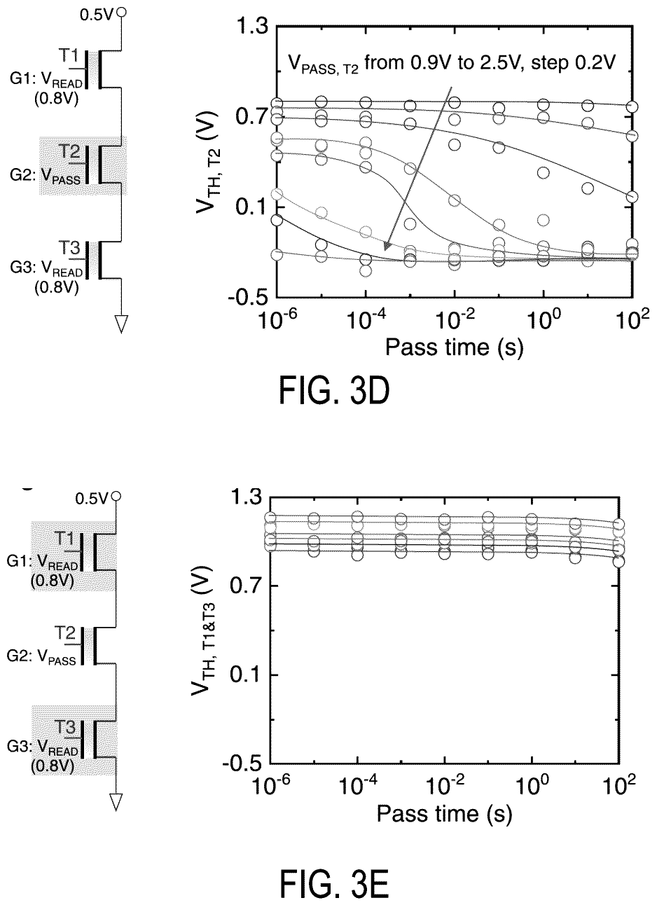

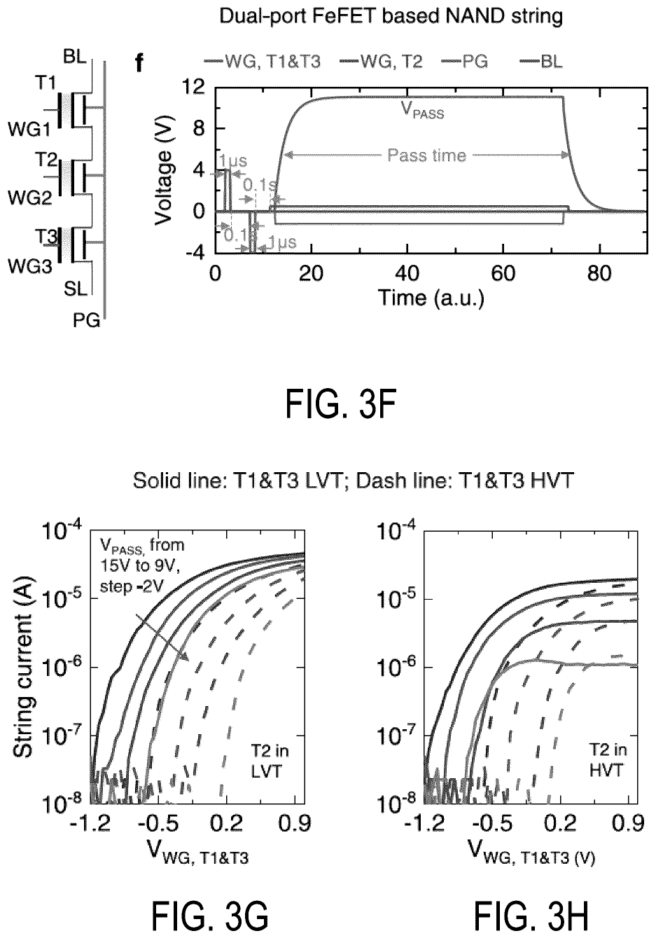

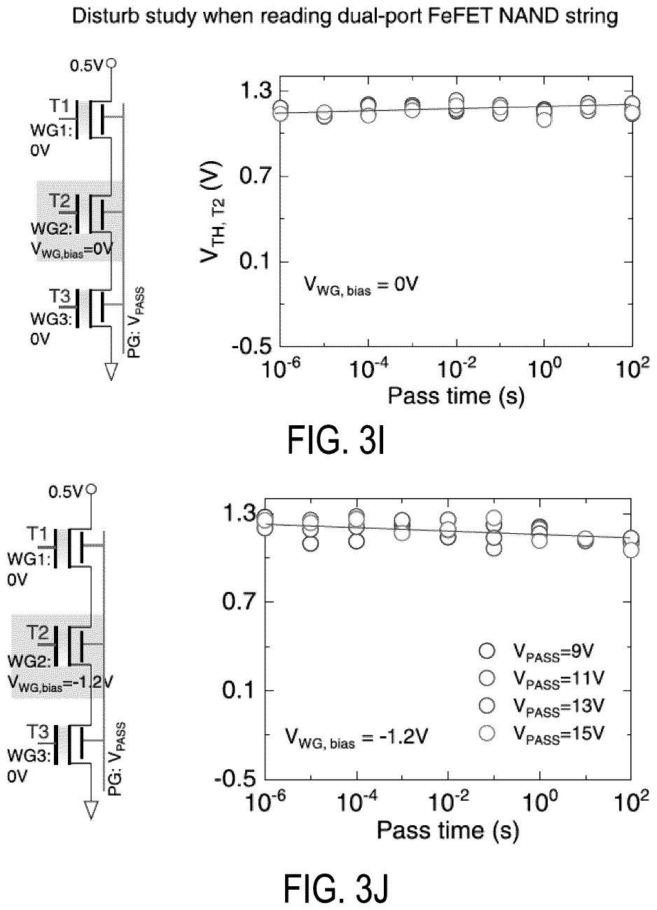

FIG. 3A illustrates an example setup and applied waveforms for a single-port FeFET-based NAND string composed of three transistors (T1, T2, T3). For ease of characterization, the gates of T1 and T3 are connected together so that they remain in the same state and operate under identical bias conditions. The waveform shows the case where VREAD and VPASS are applied to the selected and unselected transistors, respectively.

FIG. 3B illustrates the measured ID-VG characteristics of transistors T1 and T3 in the single-port NAND string when T2 is biased at VPASS=2 V. The results show proper sensing of the string current when T1 and T3 are in the low-threshold-voltage (LVT) state and in the high-threshold-voltage (HVT) state.

FIG. 3C illustrates the ID-VG characteristics of transistor T2 when designated as the selected cell, with VPASS applied to T1 and T3. The results demonstrate that the correct memory state of the selected cell can be successfully sensed regardless of the states of the unselected cells.

FIG. 3D illustrates characterization of pass disturb in the single-port NAND string. Different VPASS values ranging from 0.9 V to 2.5 V are applied to T2 during sensing of T1 and T3, and the resulting VTH of T2 is measured. Severe disturb is observed for higher VPASS values; for example, at VPASS=2.3 V, a pass time of 100 s can completely flip the memory state, highlighting instability concerns.

FIG. 3E illustrates read disturb characterization of T1 and T3 in the single-port string. The data confirm that the states of T1 and T3 are not disturbed under the applied bias, thereby demonstrating the strong dependence of disturb on stress conditions.

FIG. 3F illustrates the configuration and applied waveforms for a dual-port FeFET NAND string including transistors T1, T2, and T3. In this configuration, a shared p-well body contact is employed for pass operation, while the write gate of T2 is grounded and a pass bias is applied to a dedicated pass gate.

FIG. 3G illustrates the ID-VG characteristics of T1 and T3 in the dual-port string when the unselected transistor T2 is in the LVT state. The results show that sensing of the target cell memory state can be successfully achieved across different VPASS levels applied to the pass gate.

FIG. 3H illustrates the ID-VG characteristics of T1 and T3 when the unselected transistor T2 is in the HVT state. The data demonstrate that proper sensing is still achieved, but also indicate that a sufficiently high VPASS is required; otherwise, the HVT device may not fully turn ON, thereby limiting the string current.

FIG. 3I illustrates pass disturb characterization of the dual-port NAND string by measuring the VTH of T2 after application of pass bias to the pass gate, with the write gate of T2 grounded. The results show that the state of T2 remains unchanged even under extended pass bias times.

FIG. 3J illustrates further disturb characterization of transistor T2 in the dual-port NAND string under VPASS values ranging from 9 V to 15 V. The results indicate that no disturb occurs in T2 even under high pass bias stress. Additional measurements with the write gate biased at −1.2 V further confirm the disturb-free operation of the dual-port NAND string.

The results collectively establish that single-port NAND FeFET strings are susceptible to significant pass disturb effects under elevated VPASS conditions, whereas the dual-port NAND FeFET architecture maintains stable threshold voltage states even under extended and high-voltage pass bias operation. This pass disturb-free nature means that the memory state of an unselected cell remains stable and unaffected even when a pass bias is applied to enable access to other cells in the string. Such stability arises from the separation of the write/read and pass functions, which enables reliable disturb-free sensing, consistent string current, and robust operation of NAND arrays incorporating dual-port FeFET devices.

### Scaled Dual-Port Vertical Nand FeFET Operation and Integration

Prior verification on planar dual-port FeFET devices and NAND strings shows that pass-disturb immunity often arises from structural separation of the write/read and pass functions. The same design principle is applicable to vertical NAND arrays, where stacked layers and tight bias margins make pass-related disturbance a limiting factor for density scaling.

Dual-port operation in a vertical NAND configuration is assessed using technology computer-aided design (TCAD) simulation.

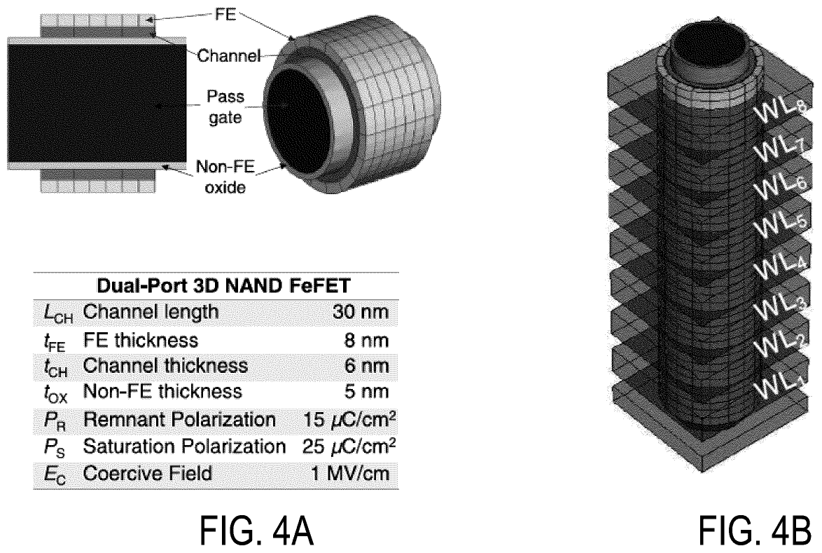

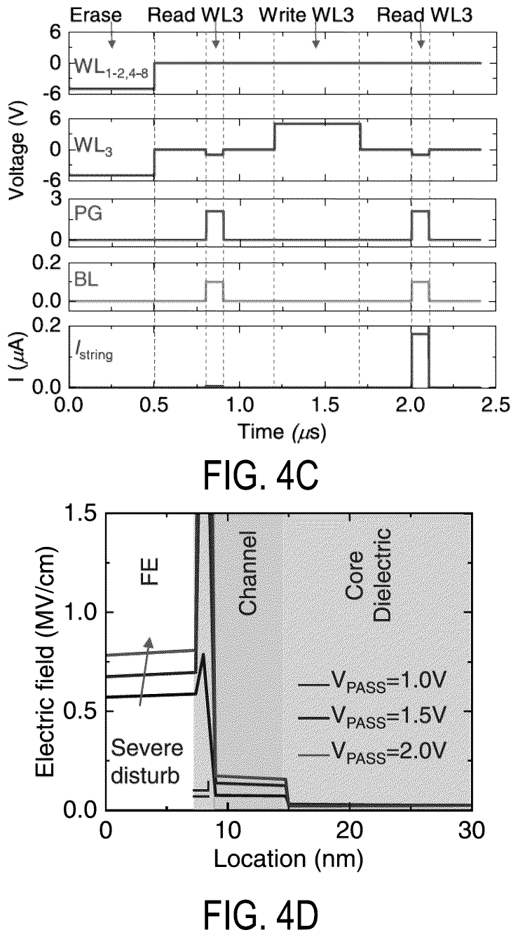

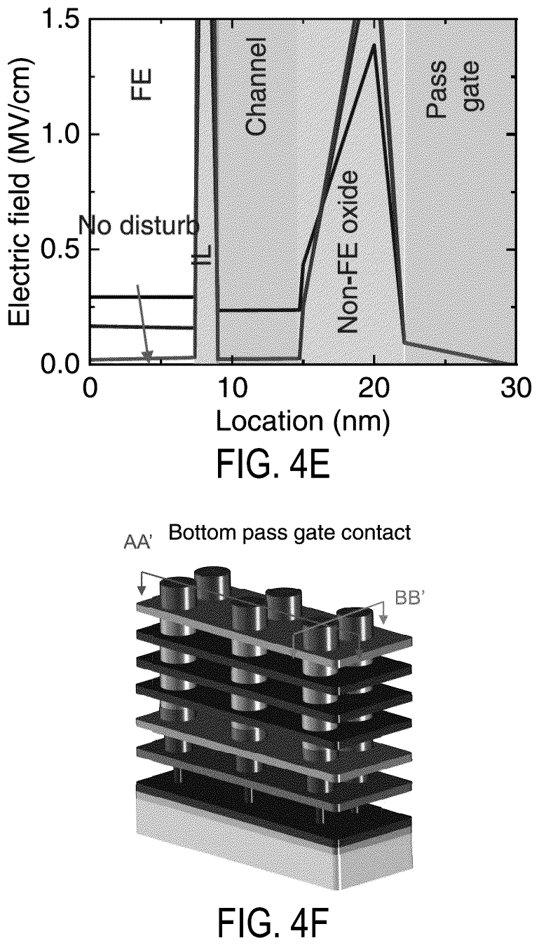

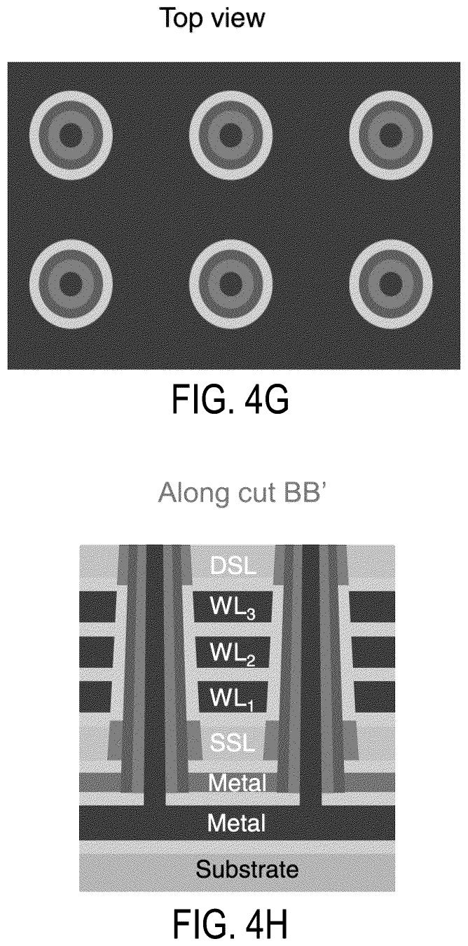

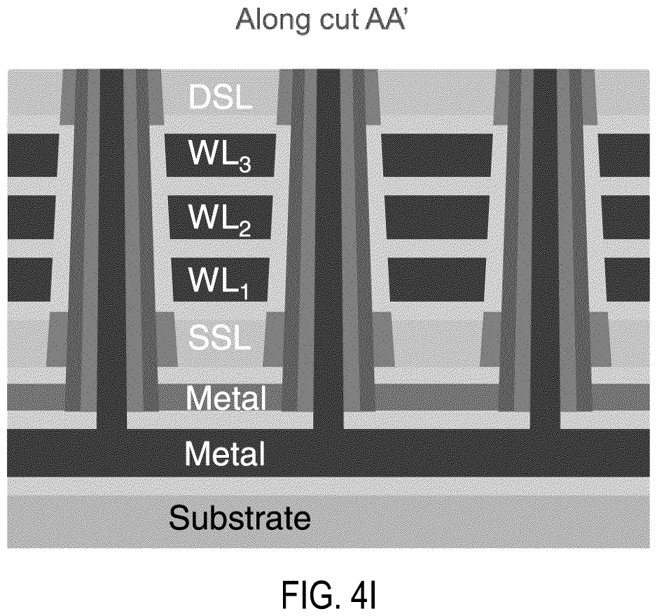

FIG. 4A illustrates a cross-section of a simulated dual-port memory cell including a ferroelectric layer (FE), a channel region, a central conductive pass-gate core electrically coupled to a non-ferroelectric pass gate, and a surrounding non-ferroelectric dielectric. Representative parameters (e.g., ˜30 nm channel length, −8 nm FE thickness, channel and non-FE thicknesses, remnant/saturation polarization, and coercive field) are provided to define a scaled device suitable for string-level analysis.

FIG. 4B illustrates a three-dimensional model of an eight-word-line (8-WL) dual-port vertical NAND string. The geometry reflects a stacked array architecture that incorporates a central pass gate implemented as a conductive core that is continuous or segmented into independently biasable sections (e.g., segments spanning 8-64 WLs with dielectric isolation and optional via straps to manage RC/IR) while maintaining the layer-by-layer word-line arrangement.

FIG. 4C illustrates erase, write, and read waveforms used in simulation with WL₃ as the selected cell. Following erase, a low string current is read; after programming WL₃ into a low-threshold-voltage (LVT) state, a higher string current is measured, indicating correct program and sense behavior for the dual-port configuration. Representative waveform amplitudes and timings include, but are not limited to, V_{READ}≈0.5-2 V, V_{PGM}≈6-15 V for vertical embodiments, V_{PASS}≈4-15 V applied only to the conductive core, and pulse widths between 50 ns and 10 ms.

FIG. 4D illustrates a simulated electric-field distribution in a single-port string. Applying VPASS to the write gate increases the depolarization component across the ferroelectric layer, creating conditions associated with severe pass disturb, particularly for high-threshold-voltage (HVT) states.

FIG. 4E illustrates a corresponding distribution for a dual-port string in which VPASS is applied to the central pass gate. The field across the ferroelectric layer is reduced relative to the single-port case, consistent with the disturb-mitigating behavior described with reference to FIGS. 1G-1I and the field maps provided in FIGS. 6A-6B.

FIG. 4F illustrates a vertical NAND-compatible 3D structure that incorporates a conductive pass-gate core within each memory hole and a pass-gate contact formed in the substrate region. The structure preserves the conventional vertical NAND stack while providing a dedicated conduction path for passing operations that is electrically isolated from ferroelectric control gates of unselected cells. In some embodiments, the conductive core can include, but is not limited to, W, TiN, or Cu with a diameter of 10-80 nm; an oxide liner (e.g., HfO₂ or SiO₂) of 3-10 nm thickness provides dielectric isolation from adjacent ferroelectric structures. The non-ferroelectric pass dielectric may have an equivalent oxide thickness (EOT) of approximately 2-7 nm, while the ferroelectric Hf₁₋ₓZrₓO₂ (x=0.4-0.6) layer may be 5-15 nm with remanent polarization Pr≈10-C/cm² and coercive field Ec≈0.5-2 MV/cm.

FIG. 4G illustrates a top view showing multiple memory holes with centrally located pass-gate cores, demonstrating array-level placement without alteration of cell pitch.

FIG. 4H illustrates a cross-section along cutline B-B′ showing word lines (WL), select lines, and the central pass gate integrated within the vertical channel.

FIG. 4I illustrates a cross-section along cutline A-A′ further detailing the stacked word-line arrangement and the central pass-gate geometry within the memory holes.

Collectively, the simulations and structural depictions indicate that the dual-port vertical NAND FeFET configuration preserves ferroelectric state integrity during pass operations by avoiding application of VPASS to the ferroelectric gates. As a result, VPASS may be selected based on channel conduction requirements rather than disturbance constraints, supporting reliable sensing over extended bias conditions. The central pass-gate approach is compatible with established vertical NAND process flows and stack geometries, providing a path for adoption in high-layer-count arrays while maintaining disturb-free behavior described elsewhere in this disclosure. In some cases, the disturb threshold referenced herein corresponds to |ΔVTH| limits of ≤50 mV after 1 ms at 25° C. (and ≤100 mV after 1 ms at 85° C.) under VPASS stress on unselected devices.

The dual-port configurations described herein achieve pass disturb-free operation in a vertical NAND FeFET string while maintaining reliable write, erase, and read characteristics. The architecture also aligns with established vertical NAND fabrication flows, as the center core pass gate may be integrated with only incremental adjustments to conventional process steps. This can result in a vertical NAND FeFET structure that preserves compatibility with existing manufacturing approaches while eliminating pass disturb effects present in single-port designs.

Single-port NAND FeFET devices can be subject to pass disturb, and the origin of such disturbance can be attributed to the combined effects of the depolarization field and the applied pass field. A dual-port FeFET architecture as described here can be utilized to address this limitation, as the structural separation of the write and read gate functions from the pass gate function can eliminate pass disturbance. A global bottom pass gate contact can be implemented and evaluated through technology computer-aided design (TCAD) simulation in connection with scaled vertical NAND memory structures. The disclosed dual-port configuration can address pass disturb in FeFET-based NAND applications and can also be applied to vertical NAND flash storage.

### Example Device Fabrication and Characterization

Some aspects of the present disclosure relate to methods and structures for fabricating and characterizing ferroelectric field-effect transistors (FeFETs), such as single-port or dual-port implementations described herein, in FEOL and/or BEOL configurations. Some embodiments provide fabrication flows, electrical characterization procedures, and/or process integration schemes that enable demonstration of pass disturb-free operation in FeFET-based NAND strings. Some aspects of the disclosure set forth representative device structures, process integration flows, and simulation data that demonstrate example structural and electrical characteristics of the disclosed dual-port FeFET architectures in three-dimensional (3D) NAND storage arrays.

In some embodiments, a fully depleted silicon-on-insulator (FDSOI) FeFET can include a poly-crystalline Si/TiN/doped HfO₂/SiO₂/p-Si gate stack. The devices can be fabricated using a 22 nm node gate-first high-x metal gate complementary metal-oxide-semiconductor (CMOS) process on 300 mm silicon wafers. In some implementations, the buried oxide layer can be formed of 20 nm SiO₂.

Fabrication of the ferroelectric gate stack process module can begin with formation of a thin SiO₂-based interfacial layer, followed by deposition of a doped HfO₂ film using atomic layer deposition (ALD). A TiN metal gate electrode can then be deposited using physical vapor deposition (PVD), after which a polycrystalline Si gate electrode can be formed. The source and drain n⁺ regions can be activated by a rapid thermal annealing (RTA) process at approximately 1000° C., which can also induce formation of the ferroelectric orthorhombic phase within the doped HfO₂.

The experimental verification was performed with a Keithley 4200-SCS Semiconductor Characterization System (Keithley system), a Tektronix TDS 2012B Two Channel Digital Storage Oscilloscope (oscilloscope). Two 4225-PMUs (pulse measurement units) were utilized to generate proper waveforms.

In the experimental characteristics, all signals were generated by the Keithley system. The drain/string currents were also captured by the Keithley system. The VTH was extracted with a constant current of ID=10⁻⁷ W/L A.

### Example Characterization of the Dual-Port BEOL IWO FeFET

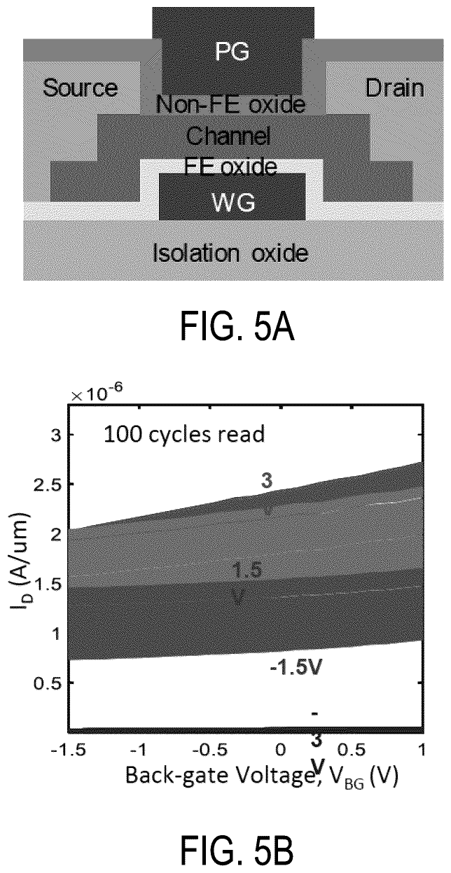

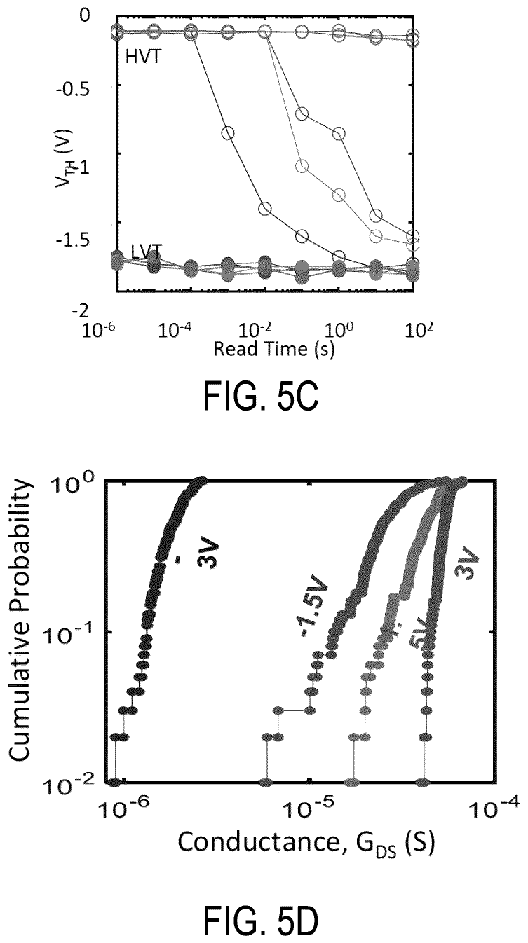

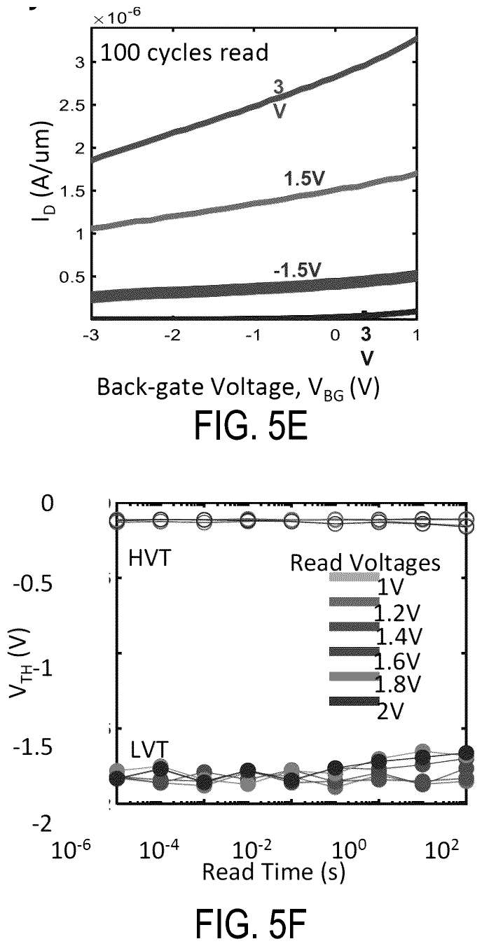

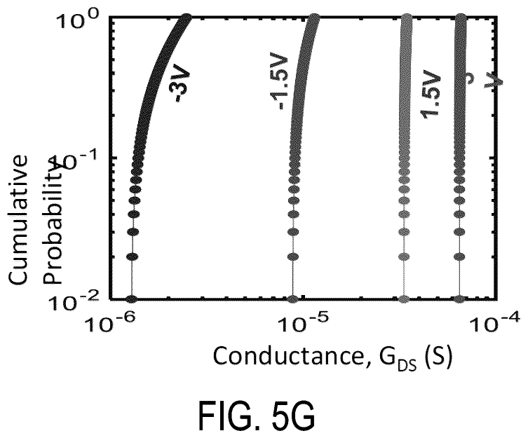

FIGS. 5A-5G illustrate device structures and electrical characterization results for dual-port BEOL indium-tungsten-oxide (IWO) FeFETs, with comparative data from single-port devices. The disclosed embodiments demonstrate that the dual-port configuration can provide stable multi-level cell (MLC) operation and substantially eliminate pass-disturb effects observed in single-port configurations. The figures further show schematic device structures, current-voltage characteristics, threshold voltage behavior under varying pass voltages and read times, and conductance distributions. These results confirm that the dual-port BEOL IWO FeFET architecture can enable disturb-free operation suitable for use in three-dimensional NAND memory arrays.

FIG. 5A illustrates a schematic view of a dual-port BEOL indium-tungsten-oxide (IWO) FeFET. The device structure can include a ferroelectric oxide layer formed of Hf_{0.5}Zr_{0.5}O₂ (HZO) positioned below the channel and a non-ferroelectric oxide layer formed of HfO₂ positioned above the channel, thereby enabling separation of write and pass operations.

FIG. 5B illustrates drain current (ID) versus back-gate voltage (VBG) characteristics of a single-port IWO FeFET. Multi-level cell (MLC) behavior can be observed, with distinguishable read currents maintained over one hundred read cycles at different applied voltages.

FIG. 5C illustrates the threshold voltage (VTH) shift of a single-port IWO FeFET measured under varying read times and different pass voltages. The data demonstrates that the single-port device exhibits significant pass-disturb effects, where longer read durations and higher pass biases result in polarization degradation.

FIG. 5D illustrates a cumulative probability distribution of the cycle-to-cycle drain-source conductance (GDS) shift for the single-port IWO FeFET. The distribution indicates substantial variability and instability in conductance across multiple read cycles when subjected to different pass biases.

FIG. 5E illustrates drain current (ID) versus back-gate voltage (VBG) characteristics of a dual-port IWO FeFET. Stable MLC operation is maintained across one hundred read cycles, demonstrating reliable readout performance without evidence of disturb under different pass voltages.

FIG. 5F illustrates the threshold voltage (VTH) behavior of the dual-port IWO FeFET measured under varying read times and pass voltages. The results demonstrate that the dual-port configuration maintains stable VTH values, confirming the absence of pass-disturb effects.

FIG. 5G illustrates the cumulative probability distribution of cycle-to-cycle drain-source conductance (GDS) shifts for the dual-port IWO FeFET. The distributions demonstrate tight clustering and minimal variability across read cycles, further validating the pass-disturb-free operation of the dual-port configuration.

FIGS. 6A and 6B illustrate the extracted electric field distribution of single-port and dual-port NAND strings obtained from technology computer-aided design (TCAD) simulations. The distributions are shown for conditions in which wordline WL6 is programmed to a high-threshold-voltage (HVT) state.

FIG. 6A illustrates the electric field distribution when a pass voltage (VPASS) of 1 V is applied. In the single-port configuration, a strong and concentrated electric field is observed within the ferroelectric layer, oriented in opposition to the ferroelectric polarization. By contrast, in the dual-port configuration, the applied biasing results in a more uniform electric field distribution, reducing adverse effects on the polarization state.

FIG. 6B illustrates the electric field distribution when a pass voltage (VPASS) of 2 V is applied. The single-port string again demonstrates a high concentration of electric field within the ferroelectric, indicating susceptibility to pass-disturb effects. The dual-port string, however, maintains a reduced and well-distributed electric field, demonstrating improved immunity to disturb phenomena even at elevated pass voltages.

### Example Process Flow for the Dual-Port Vertical FeFET-Based NAND Storage

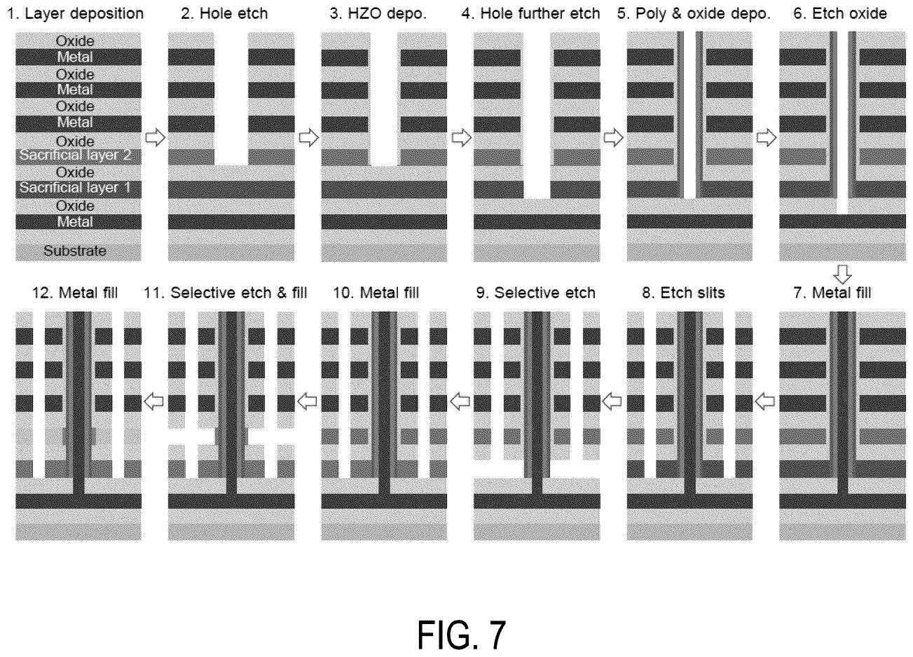

FIG. 7 illustrates an example process integration flow for forming a dual-port vertical FeFET-based NAND string in which a dedicated pass gate is incorporated into the central core region of the array. As described here, such as with reference to FIG. 1C and FIG. 1G, the use of a dedicated pass gate allows pass functions to be isolated from the ferroelectric gates of the memory cells, thereby reducing or eliminating susceptibility to pass disturb. The process flow of FIG. 7 provides a sequence compatible with three-dimensional (3D) NAND integration.

In Step 1, alternating layers of oxide and metal are deposited on a substrate to form the vertical NAND stack. In Step 2, memory holes are etched through the deposited layers to define the vertical channel regions. In Step 3, a ferroelectric hafnium zirconium oxide (HZO) layer is deposited within the memory holes, consistent with the use of ferroelectric layers described in connection with FIGS. 2C-2D. In Step 4, the memory holes are further etched to open regions for channel and gate deposition. In Step 5, a polysilicon channel material and an oxide dielectric are deposited to form the vertical channel and surrounding dielectric regions. In Step 6, selected oxide layers are etched to prepare access regions for subsequent gate metallization. In Step 7, a metal fill is performed to establish a conductive core pass-gate structure within the memory string, corresponding to the dedicated pass gate functionality described with respect to FIG. 1C; in some segmented embodiments, isolation trenches or dielectric breaks are formed to create independently biasable core segments. In Step 8, slits are etched to electrically isolate the gate structures. In Step 9, selective etching is carried out to expose the silicon channel for contact formation. In Step 10, a metal fill operation is used to form electrical contacts to the exposed channel regions. In Step 11, selective etching and fill are performed to refine and complete the contact structures. In Step 12, a final metal fill completes the channel and gate interconnections, including, for example, routing that couples V_{PASS} exclusively to the conductive core pass-gate structure and not to ferroelectric control gates of unselected cells.

Through the sequence of FIG. 7, the core pass gate can be electrically connected to the silicon channel without relying on substrate contact, as also discussed herein, such as with respect to FIGS. 4F-4I. Such an approach allows the dual-port FeFET configuration to be incorporated into a vertical NAND array with compatibility to existing process flows, while providing the disturb-free operation described elsewhere in the present disclosure.

It will be appreciated that the process flow of FIG. 7 is provided as a representative example, and that fewer, additional, or alternative steps may be employed depending on the desired implementation. For example, certain deposition steps can be combined into a single operation, intermediate etch steps can be omitted, or additional planarization steps can be introduced to improve integration with surrounding circuitry. In some embodiments, alternative materials can be substituted for the ferroelectric, dielectric, or channel layers, and the order of deposition or etching can be modified to accommodate specific process capabilities. Accordingly, the illustrated flow should not be viewed as limiting, and variations that achieve the same overall structure and functionality remain within the scope of the present disclosure.

### Example Embodiments

Embodiments of the present disclosure can be described in view of the following clauses:

A dual-port ferroelectric field-effect transistor, comprising:
a semiconductor channel between a source region and a drain region;
a ferroelectric control gate disposed adjacent to the semiconductor channel through a ferroelectric gate dielectric; and
a non-ferroelectric pass gate disposed adjacent to the semiconductor channel through a non-ferroelectric dielectric;
wherein the ferroelectric control gate is configured to set and retain a polarization state within the ferroelectric gate dielectric corresponding to a stored memory value, and
wherein, during a read or pass operation, application of a pass bias to the non-ferroelectric pass gate while the ferroelectric control gate is maintained at a reference potential establishes channel conduction substantially without applying the pass bias across the ferroelectric gate dielectric, thereby mitigating pass-disturb of the stored memory value.

### Terminology

Computer programs typically comprise one or more instructions set at various times in various memory devices of a computing device, which, when read and executed by at least one processor, will cause a computing device to execute functions involving the disclosed techniques. In some embodiments, a carrier containing the aforementioned computer program product is provided. The carrier is one of an electronic signal, an optical signal, a radio signal, or a non-transitory computer-readable storage medium.

Any or all of the features and functions described above can be combined with each other, except to the extent it may be otherwise stated above or to the extent that any such embodiments may be incompatible by virtue of their function or structure, as will be apparent to persons of ordinary skill in the art. Unless contrary to physical possibility, it is envisioned that (i) the methods/steps described herein may be performed in any sequence and/or in any combination, and (ii) the components of respective embodiments may be combined in any manner.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims, and other equivalent features and acts are intended to be within the scope of the claims.

Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Unless the context clearly requires otherwise, throughout the description and the claims, the words “comprise,” “comprising,” and the like are to be construed in an inclusive sense, as opposed to an exclusive or exhaustive sense, e.g., in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words using the singular or plural number may also include the plural or singular number respectively. The word “or” in reference to a list of two or more items, covers all of the following interpretations of the word: any one of the items in the list, all of the items in the list, and any combination of the items in the list. Likewise the term “and/or” in reference to a list of two or more items, covers all of the following interpretations of the word: any one of the items in the list, all of the items in the list, and any combination of the items in the list.

Conjunctive language such as the phrase “at least one of X, Y and Z,” unless specifically stated otherwise, is otherwise understood with the context as used in general to convey that an item, term, etc. may be either X, Y or Z, or any combination thereof. Thus, such conjunctive language is not generally intended to imply that certain embodiments require at least one of X, at least one of Y and at least one of Z to each be present. Further, use of the phrase “at least one of X, Y or Z” as used in general is to convey that an item, term, etc. may be either X, Y or Z, or any combination thereof.

In some embodiments, certain operations, acts, events, or functions of any of the algorithms described herein can be performed in a different sequence, can be added, merged, or left out altogether (e.g., not all are necessary for the practice of the algorithms). In certain embodiments, operations, acts, functions, or events can be performed concurrently, e.g., through multi-threaded processing, interrupt processing, or multiple processors or processor cores or on other parallel architectures, rather than sequentially.

Systems and modules described herein may comprise software, firmware, hardware, or any combination(s) of software, firmware, or hardware suitable for the purposes described. Software and other modules may reside and execute on servers, workstations, personal computers, computerized tablets, PDAs, and other computing devices suitable for the purposes described herein. Software and other modules may be accessible via local computer memory, via a network, via a browser, or via other means suitable for the purposes described herein. Data structures described herein may comprise computer files, variables, programming arrays, programming structures, or any electronic information storage schemes or methods, or any combinations thereof, suitable for the purposes described herein. User interface elements described herein may comprise elements from graphical user interfaces, interactive voice response, command line interfaces, and other suitable interfaces.

Embodiments are also described above with reference to flow chart illustrations and/or block diagrams of methods, apparatus (systems) and computer program products. Each block of the flow chart illustrations and/or block diagrams, and combinations of blocks in the flow chart illustrations and/or block diagrams, may be implemented by computer program instructions. Such instructions may be provided to a processor of a general purpose computer, special purpose computer, specially-equipped computer (e.g., comprising a high-performance database server, a graphics subsystem, etc.) or other programmable data processing apparatus to produce a machine, such that the instructions, which execute via the processor(s) of the computer or other programmable data processing apparatus, create means for implementing the acts specified in the flow chart and/or block diagram block or blocks. These computer program instructions may also be stored in a non-transitory computer-readable memory that can direct a computer or other programmable data processing apparatus to operate in a particular manner, such that the instructions stored in the computer-readable memory produce an article of manufacture including instruction means which implement the acts specified in the flow chart and/or block diagram block or blocks. The computer program instructions may also be loaded to a computing device or other programmable data processing apparatus to cause operations to be performed on the computing device or other programmable apparatus to produce a computer implemented process such that the instructions which execute on the computing device or other programmable apparatus provide steps for implementing the acts specified in the flow chart and/or block diagram block or blocks.

Any patents and applications and other references noted above, including any that may be listed in accompanying filing papers, are incorporated herein by reference. Aspects of the invention can be modified, if necessary, to employ the systems, functions, and concepts of the various references described above to provide yet further implementations of the invention. These and other changes can be made to the invention in light of the above Detailed Description. While the above description describes certain examples of the invention, and describes the best mode contemplated, no matter how detailed the above appears in text, the invention can be practiced in many ways. Details of the system may vary considerably in its specific implementation, while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed in the specification, unless the above Detailed Description section explicitly defines such terms. Accordingly, the actual scope of the invention encompasses not only the disclosed examples, but also all equivalent ways of practicing or implementing the invention under the claims.

To reduce the number of claims, certain aspects of the invention are presented below in certain claim forms, but the applicant contemplates other aspects of the invention in any number of claim forms. Any claims intended to be treated under 35 U.S.C. § 112(f) will begin with the words “means for,” but use of the term “for” in any other context is not intended to invoke treatment under 35 U.S.C. § 112(f). Accordingly, the applicant reserves the right to pursue additional claims after filing this application, in either this application or in a continuing application.

What is claimed is:

1. A method of performing a program or read operation in a non-volatile NAND memory string, the memory string comprising a plurality of ferroelectric field-effect transistors connected in series between a source line and a bit line, each ferroelectric field-effect transistor including a channel, a ferroelectric control gate disposed adjacent the channel through a ferroelectric gate dielectric, and a non-ferroelectric pass gate disposed adjacent the channel through a non-ferroelectric dielectric, the method comprising:
applying a program or read bias to the ferroelectric control gate of a selected ferroelectric field-effect transistor; and
applying a pass bias to the non-ferroelectric pass gate of at least one unselected ferroelectric field-effect transistor while maintaining the ferroelectric control gate of the unselected ferroelectric field-effect transistor at a reference potential,
wherein the applied pass bias drives channel conduction through the unselected ferroelectric field-effect transistor while isolating the ferroelectric gate dielectric of the unselected ferroelectric field-effect transistor from the pass bias, thereby maintaining a polarization state within the ferroelectric gate dielectric of the unselected ferroelectric field-effect transistor, the polarization state corresponding to a stored memory value, and thereby mitigating pass-disturb effects on the unselected transistor during the program or read operation in the NAND memory string.

2. The method of claim 1, further comprising performing a program-inhibit operation on the unselected ferroelectric field-effect transistor by applying a program-inhibit bias to the non-ferroelectric pass gate of the unselected ferroelectric field-effect transistor while maintaining the ferroelectric control gate of the unselected ferroelectric field-effect transistor at the reference potential, thereby raising a channel potential of the unselected ferroelectric field-effect transistor to prevent a change in the polarization state.

3. The method of claim 2, wherein the unselected ferroelectric field-effect transistor is disposed in a same NAND memory string as the selected ferroelectric field-effect transistor undergoing a program operation.

4. The method of claim 2, wherein the unselected ferroelectric field-effect transistor is coupled to a word line that is not selected for programming while an adjacent word line is selected for programming.

5. The method of claim 1, wherein the pass bias has a magnitude sufficient to enable channel conduction through the unselected ferroelectric field-effect transistor but less than a disturb threshold for the ferroelectric gate dielectric of the unselected ferroelectric field-effect transistor, thereby preserving the polarization state.

6. The method of claim 1, wherein sensing a memory state of the selected ferroelectric field-effect transistor comprises applying the read bias to the ferroelectric control gate of the selected ferroelectric field-effect transistor while maintaining the ferroelectric control gate of the unselected ferroelectric field-effect transistor at the reference potential and applying the pass bias to the non-ferroelectric pass gate of the unselected ferroelectric field-effect transistor.

7. The method of claim 1, wherein each ferroelectric field-effect transistor further comprises a conductive core extending along the NAND memory string, the conductive core being shared by the non-ferroelectric pass gates of the ferroelectric field-effect transistors.

8. The method of claim 1, wherein the non-ferroelectric pass gate of each ferroelectric field-effect transistor is formed as a global gate structure extending through a plurality of memory cells along the NAND memory string.

9. The method of claim 1, wherein applying the pass bias comprises applying a pass bias to the non-ferroelectric pass gate of at least one unselected ferroelectric field-effect transistor without applying the pass bias to any ferroelectric control gate of unselected ferroelectric field-effect transistors.

10. The method of claim 1, wherein the non-ferroelectric pass gates of the plurality of ferroelectric field-effect transistors are electrically coupled to a conductive structure extending along the NAND memory string, the conductive structure comprising a metallic core that is continuous or segmented into independently biasable sections, and during application of the pass bias the ferroelectric control gates of all unselected ferroelectric field-effect transistors in the string are maintained at the reference potential.

11. A non-volatile NAND memory string, comprising:
a plurality of ferroelectric field-effect transistors connected in series between a source line and a bit line, each ferroelectric field-effect transistor comprising:
a semiconductor channel;
a ferroelectric control gate disposed adjacent to the semiconductor channel through a ferroelectric gate dielectric; and
a non-ferroelectric pass gate disposed adjacent to the semiconductor channel through a non-ferroelectric dielectric;
wherein the ferroelectric control gate of a selected ferroelectric field-effect transistor is configured to receive a program bias or a read bias to access a polarization state within the ferroelectric gate dielectric of the selected ferroelectric field-effect transistor, the polarization state corresponding to a first stored memory value;
wherein the non-ferroelectric pass gate of an unselected ferroelectric field-effect transistor is configured to receive a pass bias that establishes channel conduction through the semiconductor channel of the unselected ferroelectric field-effect transistor while the ferroelectric control gate of the unselected ferroelectric field-effect transistor is maintained at a reference potential, thereby isolating the ferroelectric gate dielectric of the unselected ferroelectric field-effect transistor from the pass bias, maintaining a polarization state within the ferroelectric gate dielectric of the unselected ferroelectric field-effect transistor corresponding to a second stored memory value, and mitigating pass-disturb effects on the unselected ferroelectric field-effect transistor during the program bias or read bias operation in the NAND memory string.

12. The non-volatile NAND memory string of claim 11, further comprising a conductive structure electrically coupled to the non-ferroelectric pass gates along the NAND memory string, wherein the non-ferroelectric pass gate of the unselected ferroelectric field-effect transistor is configured to receive the pass bias that establishes channel conduction, while the pass bias is applied exclusively through the conductive structure to the non-ferroelectric pass gates and not to any ferroelectric control gate of unselected transistors.

13. The non-volatile NAND memory string of claim 11, wherein the plurality of ferroelectric field-effect transistors are disposed in a vertical pillar structure of a three-dimensional NAND array, the non-ferroelectric pass gates being coupled to a conductive structure extending along a longitudinal axis of the vertical pillar structure and coupled to a global pass-gate contact.

14. The non-volatile NAND memory string of claim 11, wherein the non-ferroelectric pass gate of the unselected ferroelectric field-effect transistor is configured to receive a program-inhibit bias greater than the pass bias while the ferroelectric control gate of the unselected ferroelectric field-effect transistor is maintained at the reference potential, thereby raising a channel potential of the unselected ferroelectric field-effect transistor to prevent a change in the polarization state.

15. The non-volatile NAND memory string of claim 11, wherein the unselected ferroelectric field-effect transistor is disposed in the same NAND memory string as a selected ferroelectric field-effect transistor undergoing a program operation.

16. The non-volatile NAND memory string of claim 11, wherein the pass bias has a magnitude sufficient to enable channel conduction through the unselected ferroelectric field-effect transistor but less than a disturb threshold for the ferroelectric gate dielectric of the unselected ferroelectric field-effect transistor, thereby preserving the polarization state.

17. The non-volatile NAND memory string of claim 11, wherein sensing a memory state of the selected ferroelectric field-effect transistor is performed while the ferroelectric control gate of the selected ferroelectric field-effect transistor receives the read bias, the ferroelectric control gate of the unselected ferroelectric field-effect transistor is maintained at the reference potential, and the non-ferroelectric pass gate of the unselected ferroelectric field-effect transistor receives the pass bias.

18. A non-volatile NAND memory array comprising:
a plurality of semiconductor channel pillars extending vertically along respective longitudinal axes between a source line and a bit line;
a plurality of ferroelectric control gates disposed around each semiconductor channel pillar at different positions along the respective longitudinal axes, each ferroelectric control gate separated from the semiconductor channel pillar by a ferroelectric gate dielectric;
a plurality of non-ferroelectric pass gates disposed around each semiconductor channel pillar at different positions along the respective longitudinal axes, each non-ferroelectric pass gate separated from the semiconductor channel pillar by a non-ferroelectric dielectric;
a conductive structure electrically coupled to the plurality of non-ferroelectric pass gates; and
a global pass-gate contact electrically coupled to the conductive structure.

19. The non-volatile NAND memory array of claim 18, wherein the conductive structure comprises a metallic core extending along the longitudinal axes of the semiconductor channel pillars and electrically coupled to the plurality of non-ferroelectric pass gates.

20. The non-volatile NAND memory array of claim 18, wherein the conductive structure is segmented along the longitudinal axes of the semiconductor channel pillars to permit independent biasing of different subsets of the non-ferroelectric pass gates, and wherein the ferroelectric control gates and the non-ferroelectric pass gates are alternately stacked along the longitudinal axes of the semiconductor channel pillars, each ferroelectric control gate configured as an independently addressable word line.
